(19) United States
(12) Patent Application Publication
(10) Pub. No.: US 2012/0003809 A1
(43) Pub. Date: Jan. 5, 2012

(54) ISOLATION METHOD IN SEMICONDUCTOR DEVICE

(75) Inventor: Young Deuk KIM, Icheon (KR)

(73) Assignee: Hynix Semiconductor Inc., Icheon (KR)

(21) Appl. No.: 13/176,408

(22) Filed: Jul. 5, 2011

(30) Foreign Application Priority Data
Jul. 5, 2010 (KR) 10-2010-0064508

(51) Int. Cl. H01L 21/764

(52) U.S. Cl. 438/421; 257/E21.573

(57) ABSTRACT

The present invention discloses an isolation process in a semiconductor device. In the present invention, when a SPT process is used for isolation, ISO cut patterns for cutting spacers for SPT in the unit of a specific length are first formed, and ISO partition patterns defining partition regions for forming the spacers are then formed over the ISO cut patterns. Accordingly, there are advantages in that the SPT process can be simplified and costs can be reduced according to the simplified process because the isolation process is simplified.

### CROSS-REFERENCE TO RELATED APPLICATION

The priority of Korean patent application No. 10-2010-0064508 filed on Jul. 5, 2010, the disclosure of which is hereby incorporated in its entirety by reference, is claimed.

### BACKGROUND OF THE INVENTION

1. Field of the Invention

The present invention relates to semiconductor devices and, more particularly, to an isolation method in a semiconductor device.

2. Background of the Invention

As semiconductor devices become highly integrated, pattern size, not only for patterns formed over active regions of a semiconductor substrate, but also for isolation regions for preventing electrical leakage between the patterns, is reduced.

Conventional isolation regions are formed using a local oxidation of silicon (LOCOS) process. The LOCOS method is advantageous in that it is simple and can form either wide isolation regions or narrow isolation regions. In the LOCOS method, however, the isolation region is enlarged by a bird's beak phenomenon caused by a lateral oxidization process. Accordingly, the LOCOS method is problematic in that an effective area of a source/drain region is reduced and crystalline defects are generated in the silicon substrate, causing leakage current. Moreover, as the integration degree of a semiconductor device increases and a design rule become stricter, the LOCOS method becomes impracticable.

Accordingly, a Shallow Trench Isolation (STI) method showing excellency in forming a small size of isolation region has been suggested as an alternative to the LOCOS method.

In the STI method, a nitride layer is formed on a semiconductor substrate and then patterned using a photolithography method, thereby forming a nitride layer pattern. Next, the semiconductor substrate is etched to a predetermined depth by using the nitride layer pattern as a hard mask, thereby forming trenches. The trenches are filled with an insulating layer, and then the field insulating layer is subject to a Chemical Mechanical Polishing (CMP) process.

However, the STI process requires that multiple masking processes be performed, especially as design rule becomes stricter. Accordingly, a new isolation method is necessary.

### BRIEF SUMMARY OF THE INVENTION

Various embodiments of the present invention are directed to providing a new isolation method which may also be applied to high-integrated semiconductor devices by improving the existing isolation method in semiconductor devices.

According to an embodiment of the present invention, an isolation method in a semiconductor device includes forming a pad oxide layer and a pad nitride layer over a semiconductor substrate including a cell region and a peripheral region, forming a first hard mask layer, a second hard mask layer, and a third hard mask layer over the pad nitride layer, etching the third hard mask layer to form isolation (ISO) cut patterns defining a length of active regions in the cell region in a long axis, forming ISO partition patterns over the ISO cut patterns, forming spacers for Spacer Pattern Technology (SPT) on the sidewalls of the ISO partition patterns, forming ISO peripheral patterns, defining isolation regions, over the third hard mask layer of the peripheral region, etching the third hard mask layer using the spacers and the ISO peripheral patterns as an etch barrier, thereby forming ISO patterns, and etching the second hard mask layer, the first hard mask layer, the pad nitride layer, the pad oxide layer, and the semiconductor substrate using the ISO patterns, thereby forming trenches for isolation.

An isolation method of a semiconductor device according to the present invention may further include forming spacers for extension on the sidewalls of the ISO cut patterns, before forming the ISO partition patterns.

In an isolation method of a semiconductor device according to the present invention, the first hard mask layer, the second hard mask layer, and the third hard mask layer may include an amorphous carbon layer, a siliconoxynitride (SiON) layer, and a poly layer, respectively.

In an isolation method of a semiconductor device according to the present invention, the forming the ISO partition patterns includes forming a fourth hard mask layer and a fifth hard mask layer over the ISO cut patterns, forming photoresist patterns, defining a partition region in which the spacers for SPT will be formed, on the fifth hard mask layer, and etching the fifth hard mask layer using the photoresist patterns as an etch barrier, and etching the fourth hard mask layer using the etched fifth hard mask layer as an etch barrier. Here, the fourth hard mask layer and the fifth hard mask layer include an amorphous carbon layer and a siliconoxynitride (SiON) layer, respectively.

In an isolation method of a semiconductor device according to the present invention, a process of etching the fourth hard mask layer may be performed according to a plasma etch method using an oxygen (O₂) gas as a main etch gas.

In an isolation method of a semiconductor device according to the present invention, the spacers for SPT include an Ultra Low Temperature Oxide (ULTO) layer or a Spin-On Glass (SOG) oxide layer.

In an isolation method of a semiconductor device according to the present invention, the forming the ISO peripheral patterns includes forming a sixth hard mask layer and a seventh hard mask layer over the spacers for SPT and the third hard mask layer, forming photoresist patterns, defining the isolation regions of the peripheral region on the seventh hard mask layer, and etching the seventh hard mask layer using the photoresist patterns as an etch barrier and etching the sixth hard mask layer using the etched seventh hard mask layer as an etch barrier. Here, the sixth hard mask layer includes a High Temperature Spin-On Carbon (HT-SOC) layer or a Multi-Function Hard Mask (MFHM) layer. The seventh hard mask layer includes a siliconoxynitride (SiON) layer.

### BRIEF DESCRIPTION OF THE DRAWINGS

The above and other aspects, features, and other advantages of the subject matter of the present disclosure will be more clearly understood from the following detailed description taken in conjunction with the accompanying drawings, in which:

FIG. 1 is a plan view showing active regions formed in a cell region;

FIGS. 2 to 10 are cross-sectional views illustrating an isolation method according to an embodiment of the present invention; and

FIG. 11 is a cross-sectional view illustrating another embodiment of the present invention.

### DESCRIPTION OF EMBODIMENTS

Exemplary embodiments are described herein with reference to cross-sectional illustrations that are schematic illustrations of exemplary embodiments (and intermediate structures). Variations in shapes are to be expected. Thus, exemplary embodiments should not be construed as limited to a particular shape illustrated herein, but may include deviations in shape that result, for example, from manufacturing processes. In the drawings, lengths and sizes of layers and regions may be exaggerated to assist understanding. Like reference numerals in the drawings denote like elements. It is also understood that when a layer is referred to as being “on” another layer or substrate, it can be directly on the other layer or substrate, or intervening layers may also be present.

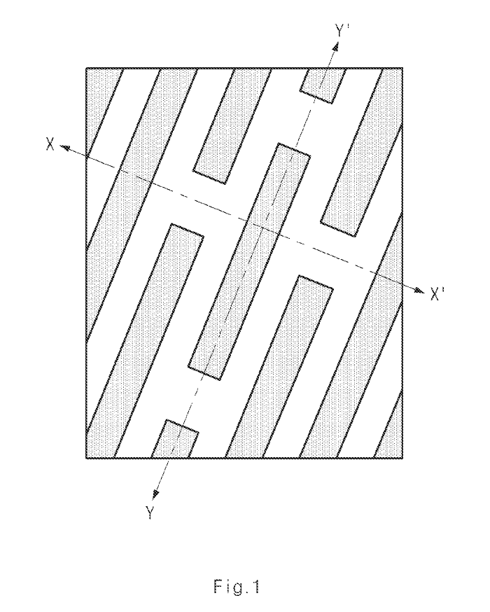

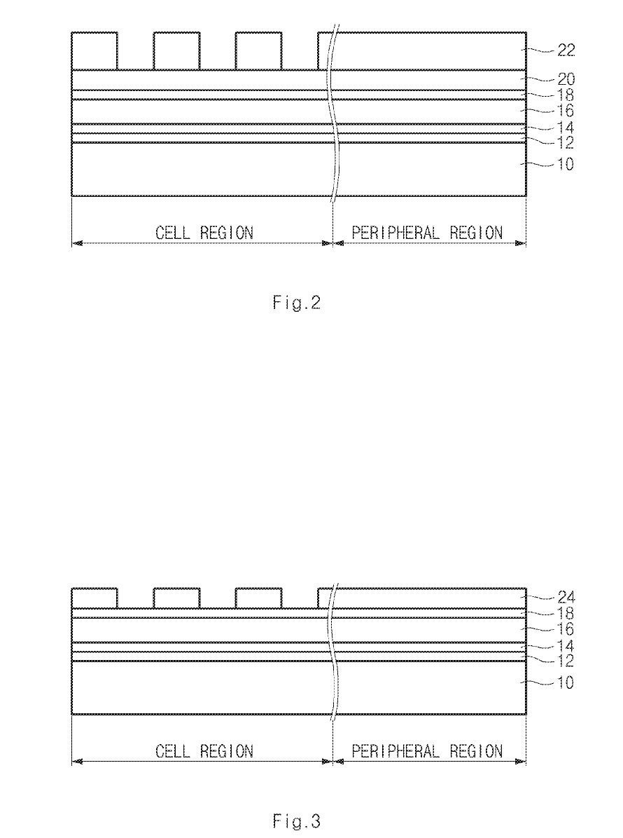

FIG. 1 is a plan view showing active regions formed in a cell region. FIGS. 2 to 10 are cross-sectional views illustrating an isolation method according to an embodiment of the present invention.

In this embodiment, FIG. 1 shows active regions in a cell region, and FIGS. 2 to 10 show the cross-sectional views of the cell region taken along line X-X′ in FIG. 1 and a peripheral region as well.

Referring first to FIG. 2, a pad oxide layer 12 and a pad nitride layer 14 are formed over a semiconductor substrate 10. An amorphous carbon layer 16, a siliconoxynitride (SiON) layer 18, and a poly layer 20, all of which serve as a hard mask, are sequentially stacked over the pad nitride layer 14.

After a photoresist layer (not shown) is formed on the poly layer 20, photoresist patterns 22 are formed by performing exposure and development processes using an ISO cut mask (not shown). The ISO cut mask is a mask for defining the length of the active region in the long axis. The ISO cut mask is used to cut spacers, formed by a Spacer Pattern Technology (SPT) process in an isolation method using SPT, in the unit of the length of the active region.

Referring next to FIG. 3, the poly layer 20 is etched by using the photoresist patterns 22 as an etch barrier, thereby forming ISO cut patterns 24. Next, the photoresist patterns 22 are removed.

In general in an SPT process, ISO partitions for forming spacers are first formed and the spacers are then formed using the partitions. Next, ISO cut mask is used to cut the spacers for forming the active regions. In the present embodiment, however, prior to the formation of the ISO partitions, the ISO cut patterns 24 are formed by etching the poly layer 20 using the ISO cut mask.

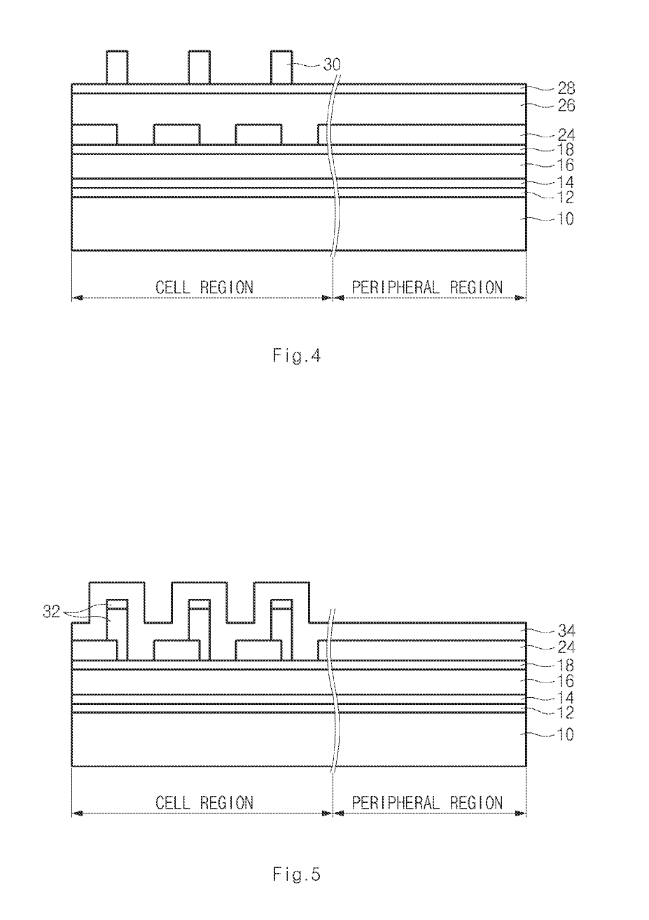

Referring to FIG. 4, an amorphous carbon layer 26 and a siliconoxynitride (SiON) layer 28 are sequentially deposited over the ISO cut patterns 24 and the siliconoxynitride (SiON) layer 18 exposed by the ISO cut patterns 24.

In other words, in the present embodiment, the five layers, including the amorphous carbon layer 16, the siliconoxynitride (SiON) layer 18, the ISO cut patterns 24 that are formed of a poly layer, the amorphous carbon layer 26, and the siliconoxynitride (SiON) layer 28, all of which serve as a hard mask layer, are sequentially formed.

After a photoresist layer is formed on the siliconoxynitride (SiON) layer 28, photoresist patterns 30 are formed by performing exposure and development processes using an ISO partition mask (not shown). Here, the ISO partition mask is a mask for defining partition regions.

Referring to FIG. 5, the siliconoxynitride (SiON) layer 28 is etched by using the photoresist patterns 30 as an etch barrier. The amorphous carbon layer 26 is selectively etched by using the etched siliconoxynitride (SiON) layer as an etch barrier, thereby forming ISO partition patterns 32.

Here, the photoresist patterns 30 are fully removed in the process of etching the amorphous carbon layer 26. That is, the photoresist layer has an etch rate 2 to 3 times greater than that of the amorphous carbon layer 26. Accordingly, the photoresist patterns 30 can be fully removed by controlling the thickness of the photoresist layer or excessively etching the amorphous carbon layer 26. Furthermore, the process of etching the amorphous carbon layer 26 may be performed by a plasma etch method using oxygen (O₂) gas as a main etch gas.

Next, an insulating layer 34 for forming spacers for SPT is formed on the entire structure.

Here, the insulating layer 34 may be made of Ultra Low Temperature Oxide (ULTO), Cformed at a very low temperature of 50° C. to 100° C., or Spin-On Glass (SOG) oxide. However, the ULTO can be more easily removed by hydrofluoric (HF) acid or Buffered Oxide Echant (BOE), compared with an oxide layer formed at a temperature of 50° C. to 100° C. or higher. It is preferred that the ULTO be used as the insulating layer 34 for spacers.

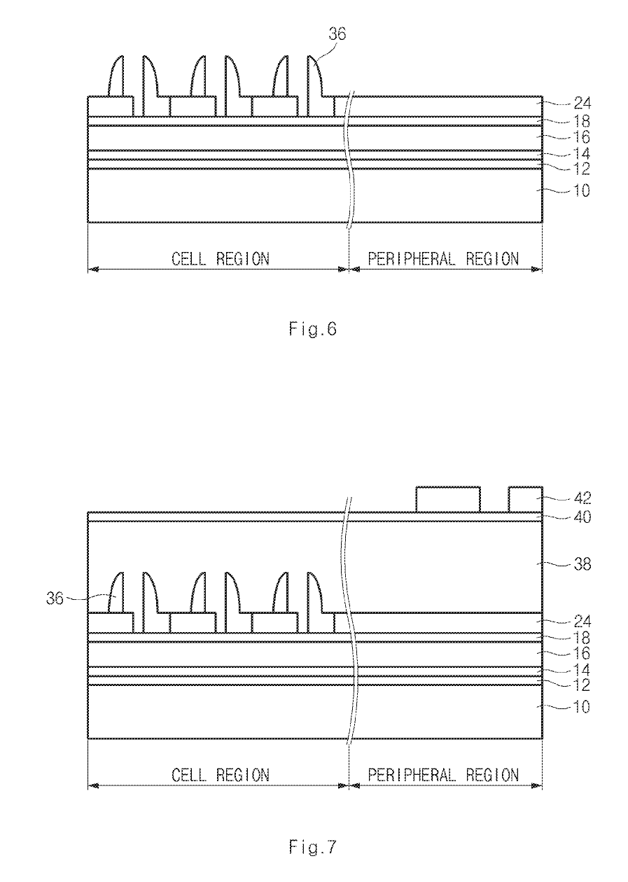

Referring to FIG. 6, spacers 36 are formed at sidewalls of the ISO partition patterns 32 by etching back the insulating layer 34 for spacers. Next, the ISO partition patterns 32 are removed.

Referring to FIG. 7, a High Temperature Spin-On Carbon (HT-SOC) layer 38 and a siliconoxynitride (SiON) layer 40, both of which are used as a hard mask, are sequentially deposited over the resultant structure of FIG. 5. Here, a Multi-Function Hard Mask (MFHM) layer, functioning both as an anti-reflective coating layer and a hard mask, may be formed instead of the HT-SOC layer.

A photoresist layer (not shown) is formed on the siliconoxynitride (SiON) layer 40 and then patterned using an ISO peripheral mask (not shown), thereby forming photoresist patterns 42 defining the isolation regions in a peripheral region. Here, the ISO peripheral mask is a mask defining the isolation regions in the peripheral region.

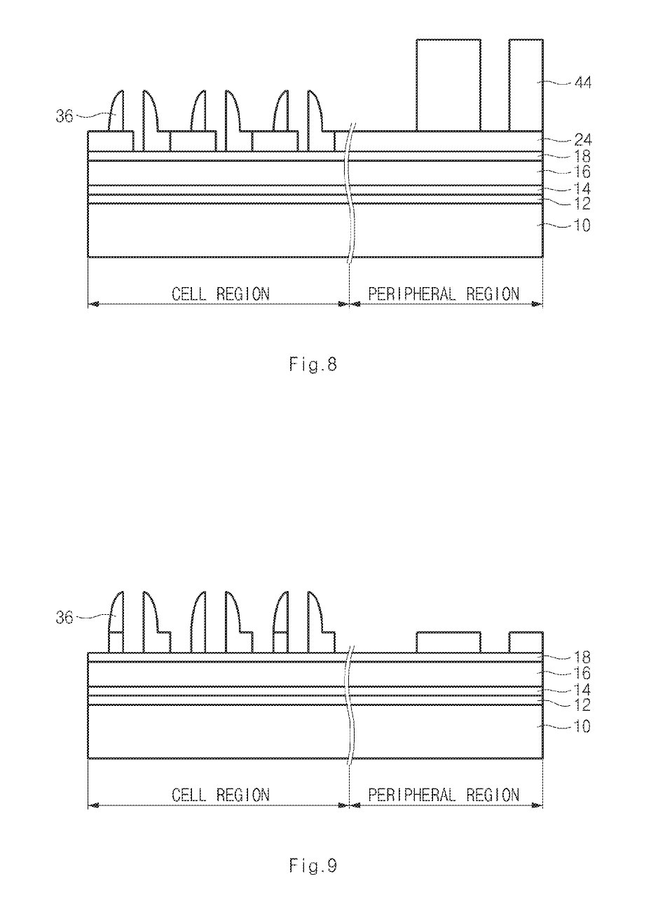

Referring to FIG. 8, the siliconoxynitride (SiON) layer 40 is etched and patterned by using the photoresist patterns 42 as an etch barrier. The HT-SOC layer (or the MFHM layer) 38 is etched by using the patterned siliconoxynitride (SiON) patterns (not shown) as an etch barrier, thereby forming ISO peripheral patterns 44 in the peripheral region. Here, the HT-SOC layer 38 formed in the cell region is fully removed.

Referring to FIG. 9, the ISO cut patterns 24 and insulating materials (not shown) remaining between the ISO cut patterns 24 are etched by using the spacers 36 as an etch barrier in the cell region and using the ISO peripheral patterns 44 as an etch barrier in the peripheral region.

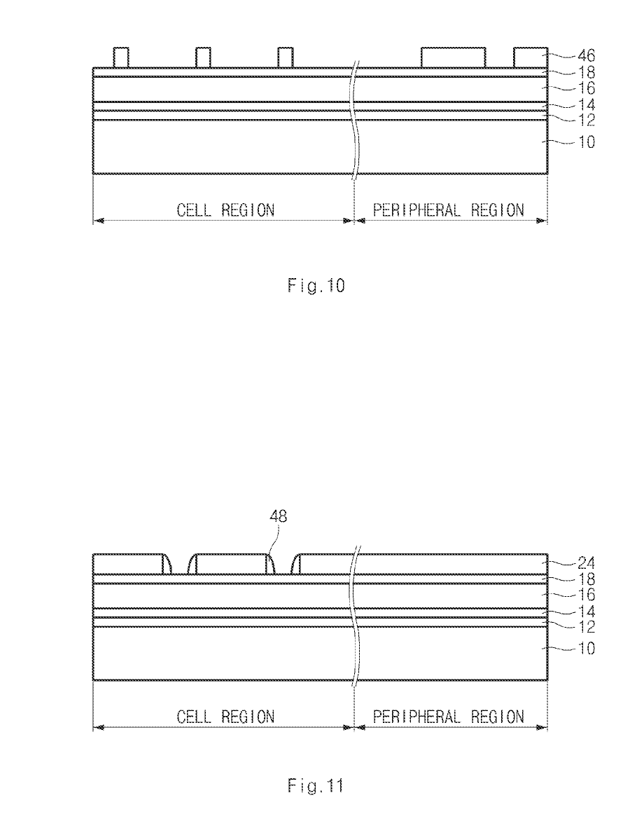

Referring to FIG. 10, the spacers 36 are removed by performing a wet cleaning process. Accordingly, ISO patterns 46 defining the active regions are formed in the cell region and the peripheral region.

Trenches (not shown) for isolating the active regions are formed by etching the hard mask layers 16 and 18, the pad nitride layer 14, the pad oxide layer 12, and the semiconductor substrate 10 using the ISO patterns 46. Isolation layers (not shown) to define the active regions are formed by filling the trenches with an insulating layer. Here, the process of etching the amorphous carbon layer 16 may be performed by a plasma etch method using oxygen (O₂) gas as a main etch gas. Detailed description on the process of forming the isolation layers using the ISO patterns 46 is known in the related art and is thus omitted.

As described above, in the present invention, when the SPT process is used for isolation, after the ISO partitions are formed, the ISO partitions are not cut in the unit of the length of the active region in the long axis using a cut mask. Instead, in the present invention, the cut patterns are formed first using the cut mask, and then the ISO partitions are formed. Accordingly, the process can be simplified.

FIG. 11 is a cross-sectional view taken along line Y-Y′ of FIG. 1.

In this embodiment, before the amorphous carbon layer 26 and the siliconoxynitride (SiON) layer 28 are sequentially deposited after the ISO cut patterns 24 are formed (as in FIG. 3), spacers 48 for extension are formed at sidewalls of the ISO cut patterns 24. Accordingly, the length of the active region in the long axis can be extended. In other words, after the ISO cut patterns 24 are formed (as in FIG. 3), an insulating layer (for example, a nitride layer (not shown)) for spacers is deposited over the ISO cut patterns 24 and the siliconoxynitride (SiON) layer 18 exposed by the ISO cut patterns 24. The insulating layer is etched back to form the spacers 48 at sidewalls of the ISO cut patterns 24.

Subsequent processes are performed in the same way shown as in FIGS. 4 to 10.

The above embodiments of the present invention are illustrative and not limitative. Various alternatives and equivalents are possible. Other additions, subtractions, or modifications are obvious in view of the present disclosure and are intended to fall within the scope of the appended claims.

What is claimed is:

1. An isolation method in a semiconductor device, the method comprising:
forming a pad oxide layer and a pad nitride layer over a semiconductor substrate including a cell region and a peripheral region;
forming a first hard mask layer, a second hard mask layer, and a third hard mask layer over the pad nitride layer;
etching the third hard mask layer to form isolation (ISO) cut patterns defining a length of active regions in the cell region;
forming ISO partition patterns over the ISO cut patterns;
forming first and second spacers using Spacer Pattern Technology (SPT) at first and second longitudinal sidewalls of the ISO partition patterns respectively, wherein the first spacer is formed over the second hard mask layer with interposing the ISO cut patterns and the second spacer is formed over the second hard mask layer without interposing the ISO cut pattern;
forming ISO peripheral patterns over the third hard mask layer of the peripheral region, the ISO peripheral patterns defining isolation regions in the peripheral region;
etching the third hard mask layer using the first and the second spacers and the ISO peripheral patterns as an etch barrier;
removing the first and the second spacers to form ISO patterns formed of the third hard mask layer; and
etching the second hard mask layer, the first hard mask layer, the pad nitride layer, the pad oxide layer, and the semiconductor substrate using the ISO patterns to form trenches for isolation.

2. The isolation method according to claim 1, the method further comprising forming spacers at widthwise sidewalls of the ISO cut patterns before forming the ISO partition patterns.

3. The isolation method according to claim 1, wherein the first hard mask layer comprises an amorphous carbon layer.

4. The isolation method according to claim 3, wherein the process of etching the first hard mask layer is performed by a plasma etch method using an oxygen (O₂) gas as a main etch gas.

5. The isolation method according to claim 1, wherein the second hard mask layer comprises a siliconoxynitride (SiON) layer.

6. The isolation method according to claim 1, wherein the third hard mask layer comprises a poly layer.

7. The isolation method according to claim 1, wherein the forming the ISO partition patterns comprises:
forming a fourth hard mask layer and a fifth hard mask layer over the ISO cut patterns;
forming photoresist patterns over the fifth hard mask layer; and
etching the fifth hard mask layer using the photoresist patterns as an etch barrier and etching the fourth hard mask layer using the etched fifth hard mask layer as an etch barrier.

8. The isolation method according to claim 7, wherein the fourth hard mask layer comprises an amorphous carbon layer.

9. The isolation method according to claim 8, wherein the process of etching the fourth hard mask layer is performed by a plasma etch method using an oxygen (O₂) gas as a main etch gas.

10. The isolation method according to claim 7, wherein the fifth hard mask layer comprises a siliconoxynitride (SiON) layer.

11. The isolation method according to claim 1, wherein the first and the second spacers each comprise a Ultra Low Temperature Oxide (ULTO) layer, a Spin-On Glass (SOG) oxide layer or a combination thereof.

12. The isolation method according to claim 1, wherein the-forming-the-ISO-peripheral patterns comprises:
forming a sixth hard mask layer and a seventh hard mask layer over the spacers for SPT and the third hard mask layer in the cell region and the peripheral region;
forming photoresist patterns, defining the ISO peripheral patterns, over the seventh hard mask layer; and
etching the seventh hard mask layer using the photoresist patterns as an etch barrier and etching the sixth hard mask layer using the etched seventh hard mask layer as an etch barrier.

13. The isolation method according to claim 12, wherein the sixth hard mask layer comprises a High Temperature Spin-On Carbon (HT-SOC) layer, a Multi-Function Hard Mask (MFHM) layer or a combination thereof.

14. The isolation method according to claim 12, wherein the seventh hard mask layer comprises a siliconoxynitride (SiON) layer.

15. A method for forming a device isolation pattern for a semiconductor device, the method comprising:
forming a first mask pattern over a substrate, the first mask pattern being an island pattern;
forming a second mask pattern partially overlapped with the first mask pattern;
forming a first spacer at a sidewall of the second mask pattern, the first spacer being formed over the first mask pattern;
patterning the first mask pattern using the first spacer to form a third mask pattern; and
patterning the substrate using the third mask pattern to form a device isolation pattern.

16. A method for forming a device isolation pattern for semiconductor device, the method comprising:
forming a first mask pattern over a substrate, the first mask pattern being an island pattern;
forming a second mask pattern partially overlapped with the first mask pattern;
forming first and second spacers at sidewalls of the second mask pattern, the first spacer being formed over the first mask pattern and the second spacer being formed over the substrate with interposing the first mask pattern;
patterning the first mask pattern using the first spacer to form a third mask pattern; and
patterning the substrate using the third mask pattern to form a device isolation pattern.
